(19) United States
(12) Patent Application Publication
(10) Pub. No.: US 2009/0127706 A1
(43) Pub. Date: May 21, 2009

(54) CHIP STRUCTURE, SUBSTRATE STRUCTURE, CHIP PACKAGE STRUCTURE AND PROCESS THEREOF

(75) Inventors: Chi-Chih Shen, Kaohsiung City (TW); Jen-Chuan Chen, Taoyuan County (TW); Hui-Shan Chang, Taoyuan County (TW); Tommy Pan, Taipei City (TW)

Correspondence Address: J C PATENTS, INC., 4 VENTURE, SUITE 250, IRVINE, CA, 92618, US

(73) Assignee: ADVANCED SEMICONDUCTOR ENGINEERING, INC., Kaohsiung (TW)

(21) Appl. No.: 12/248,562

(22) Filed: Oct. 9, 2008

(30) Foreign Application Priority Data
Nov. 19, 2007 (TW) 96143775

(51) Int. Cl. H01L 23/498

(52) U.S. Cl. 257/737; 257/E23.068

(57) ABSTRACT

A chip package structure and process are provided; the structure includes a substrate, a chip, a solder layer and at least a stud bump. The substrate has at least a contact pad, and the chip has an active surface where at least a bonding pad is disposed. The stud bump is disposed on the bonding pad of the chip or on the contact pad of the substrate, and the stud bump joints with the solder layer to fix the chip on the substrate. The stud bump is made of gold-silver alloy containing silver below 15% by weight.

### CROSS-REFERENCE TO RELATED APPLICATION

This application claims the priority benefit of Taiwan application serial no. 96143775, filed Nov. 19, 2007. The entirety of the above-mentioned patent application is hereby incorporated by reference herein and made a part of this specification.

### BACKGROUND OF THE INVENTION

1. Field of the Invention

The present invention relates to a semiconductor package structure, and more particularly, to a chip structure, a substrate structure, a chip package structure, and a process of fabricating the chip package structure.

2. Description of Related Art

In the current era, a semiconductor industry is characterized by high integration and great maturity of technology. To comply with diverse market demands, various chip package structures including optoelectronic products, light emitting devices, and light sensing devices (image sensors) are developed and manufactured by performing a process for fabricating semiconductors, thus giving rise to significant reduction of manufacturing costs.

FIG. 1 is a schematic cross-sectional view of a conventional chip package structure. As shown in FIG. 1, a plurality of bumps 110 and an under bump metallurgy (UBM) 108 are formed on an active surface 102 of a chip 100. After the fabricated chip 100 is flipped around, the bumps 110 disposed on the active surface 102 of the chip 100 are electrically connected to a contact pad 122 of a substrate 120, so as to form a chip package structure 130. Here, the bumps 110 are, for example, printed solder bumps or electroplated conductive bumps. In addition, the bumps 110 can also be gold bumps formed by wire bonding and electric flame off (EFO).

The conventional gold bumps are referred to as stud bumps containing gold and palladium, wherein the percentage of gold and the percentage of palladium are 99% and 1% by weight, respectively. As the stud bumps 110 and the contact pad 122 of the substrate 120 are bonded via solder, not only gold-tin eutectic alloy may be developed, but also defects including intermetallic compounds (IMCs) and voids may be generated in junctions of the stud bumps 110 and the contact pad 122 of the substrate 120. Said defects may result in formation of slits, and thereby a bonding strength between the stud bumps 110 and the contact pad 122 and the lifetime of the stud bumps 110 and the contact pad 122 are reduced. In addition, after a long time operation, the gold in the stud bumps 110 is diffused to the solder, which may bring about a loss of the gold in the stud bumps 110 or a variation in the composition of the stud bumps 110. In view of the foregoing, it is imperative to further improve the reliability of the conventional stud bumps.

### SUMMARY OF THE INVENTION

The present invention is directed to a chip structure, a substrate structure, a chip package structure, and a process of fabricating the chip package structure, so as to remove conventional defects and to improve the reliability of stud bumps.

The present invention provides a chip structure including a chip and at least a stud bump. The chip has an active surface where at least a bonding pad is disposed. The stud bump is disposed on the bonding pad of the chip. Here, the stud bump is made of a gold-silver alloy, wherein the percentage of silver is equal to or less than 15% by weight.

The present invention further provides a substrate structure including a substrate and at least a stud bump. The substrate has at least a contact pad. The stud bump is disposed on the contact pad of the substrate. Here, the stud bump is made of a gold-silver alloy, wherein the percentage of silver is equal to or less than 15% by weight.

The present invention further provides a chip package structure including a substrate, a chip, and at least a stud bump. The substrate has at least a contact pad, and the chip has an active surface where at least a bonding pad is disposed. The stud bump is disposed on the contact pad of the substrate or on the bonding pad of the chip. Here, the stud bump is made of a gold-silver alloy, wherein the percentage of silver is equal to or less than 15% by weight.

In an embodiment of the present invention, the substrate is a printed circuit board, while the chip is a flip chip.

In an embodiment of the present invention, the chip package structure further includes a solder layer disposed on the contact pad of the substrate. In another embodiment of the present invention, the solder layer is disposed on the bonding pad of the chip.

The present invention further provides a process of fabricating a chip package. First, a substrate and a chip are provided. The substrate has at least a contact pad, while the chip has at least a bonding pad. Next, at least a stud bump is formed on the bonding pad of the chip, such that the chip is fixed to the substrate through the stud bump. Here, the stud bump is made of a gold-silver alloy, wherein the percentage of silver is equal to or less than 15% by weight.

The present invention further provides another process of fabricating a chip package. First, a substrate and a chip are provided. The substrate has at least a contact pad, while the chip has at least a bonding pad. Next, at least a stud bump is formed on the contact pad of the substrate, such that the chip is fixed to the substrate through the stud bump. The stud bump is made of a gold-silver alloy, wherein the percentage of silver is equal to or less than 15% by weight.

In an embodiment of the present invention, a method of forming the stud bump includes wire bonding and EFO.

In an embodiment of the present invention, a method of fixing the chip to the substrate includes thermocompression or ultrasonic vibration bonding.

In the present invention, the gold-silver alloy containing 5%˜15% of silver by weight is used as the stud bump. Thereby, during a soldering operation, the formation of IMCs and the loss of gold can be prevented since the solder layer is composed of a silver-diffusion constituent.

In order to make the aforementioned and other objects, features and advantages of the present invention more comprehensible, several embodiments accompanied with figures are described in detail below.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1 is a schematic cross-sectional view of a conventional chip package structure.

FIGS. 2A through 2C are schematic views of a chip package structure and a process of fabricating the same according to a first embodiment of the present invention.

FIGS. 3A through 3C are schematic views of a chip package structure and a process of fabricating the same according to a second embodiment of the present invention.

FIG. 4 is a schematic view of a chip structure according to another embodiment of the present invention.

FIG. 5 is a schematic view of a substrate structure according to still another embodiment of the present invention.

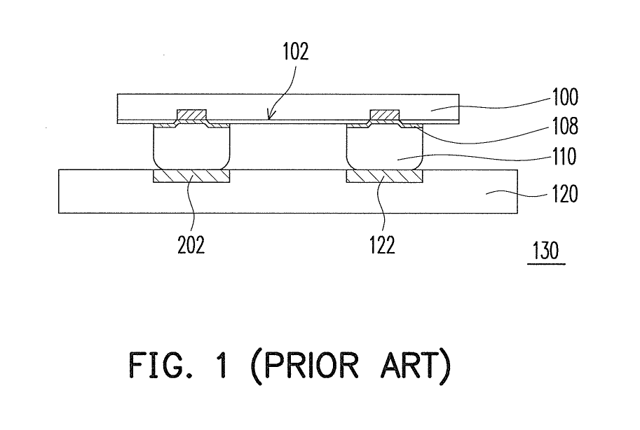

### DESCRIPTION OF EMBODIMENTS

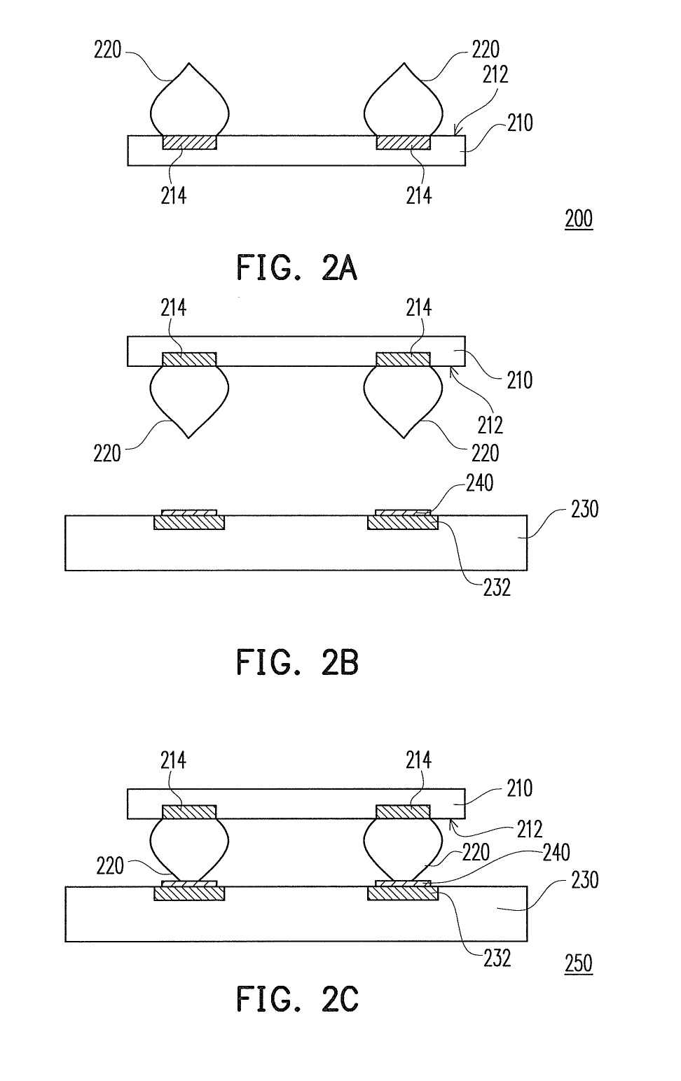

FIGS. 2A through 2C are schematic views of a chip package structure and a process of fabricating the same according to a first embodiment of the present invention. Referring to FIG. 2A, a chip package structure 200 includes a chip 210 and a plurality of stud bumps 220. A plurality of bonding pads 214 are disposed on an active surface 212 of the chip 210, and the bonding pads 214 are, for example, made of aluminumn. Here, the bonding pads 214 serve as input/output interfaces of electronic signals. The chip 210 can be used in ball grid array (BGA) structures, such as semiconductor devices including light sensing devices, light emitting devices, or processors. The stud bumps 220 are bump-shaped gold balls formed by melting gold wires with use of a wire-bonding machine. After the gold balls are pressed onto the bonding pads 214, the gold wires are cut off. The use of the gold bumps formed by wire bonding and EFO is conducive to accelerating the manufacturing process and improving throughput, so as to effectively reduce manufacturing costs.

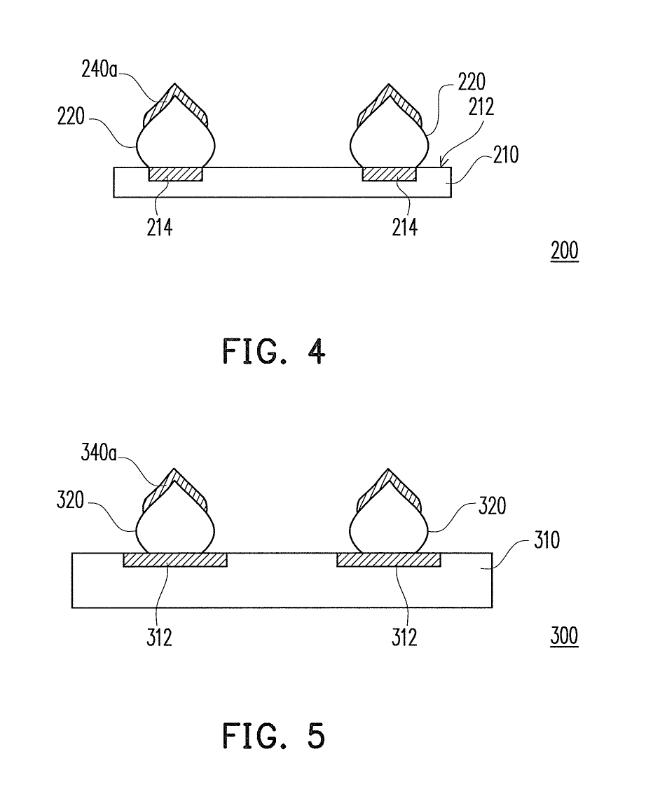

Next, a flip chip bonding process is carried out. As shown in FIG. 2B, the chip 210 is flipped around, and a sucking device (not shown) is employed for sucking a back surface of the chip 210. Thereby, the chip 210 can be electrically connected to a substrate 230 through the stud bumps 220, and then a chip package structure 250 indicated in FIG. 2C is formed. The substrate 230 is, for example, a printed circuit board, and the substrate 230 is equipped with a plurality of contact pads 232 made of copper, for example. Prior to the implementation of the flip chip bonding process, a solder layer 240 can be formed on the contact pads 232 of the substrate 230 by printing. The solder layer 240 can be made of a solder paste, a lead-free solder, and so on. Here, the solder layer 240 is utilized for bonding the stud bumps 220 disposed on the chip 210, such that the chip 210 can be fixed to the substrate 230. In the present embodiment, a method of fixing the chip 210 to the substrate 230 is, for example, a thermocompression method, such that the gold bumps and the solder layer 240 can result in gold-tin eutectic alloy, and a bonding strength between the solder layer 240 and the gold bumps can be improved as well. In addition, referring to FIG. 4, the solder layer not only can be formed on the contact pads 232 of the substrate 230, but also can be formed on each of the stud bumps 220 according to another embodiment. For instance, a required solder layer 240a can be formed by adhering the solder to the stud bumps 220 without fabricating a stencil, thus reducing the manufacturing costs. On the other hand, the chip can also be fixed to the substrate by performing an ultrasonic vibration bonding process in no need of forming the solder layer 240 on the contact pads 232 of the substrate 230 or forming the solder layer 240a on the stud bumps 220. Thereby, the manufacturing process can be simplified.

It should be noted that the stud bumps 220 of the present invention are made of a gold-silver alloy containing 15% or less than 15% of silver by weight, so as to prevent the gold of the stud bumps 220 from diffusing to the solder layer 240 or to resist the formation of the IMCs when the stud bumps 220 are welded to the solder layer 240. In detail, silver would be diffused to the solder layer 240, such that the solder layer 240 no longer contains tin only. A combination layer is thus formed. Here, the combination layer contains alloy of 0.5%˜3.5% of silver by weight, gold and tin. During a soldering operation, the formation of the IMCs and the loss of gold can be prevented because the solder layer 240 is composed of a silver-diffusion constituent.

In the present embodiment, the stud bumps 220 of the chip package structure 250 are made of gold wires with an improved strength. The gold wires contain 15% or less than 15% of silver by weight. In comparison with the conventional gold wires containing 99% of gold, the gold wires of the present invention are characterized by better wire bonding strength, greater bond-off performance, and uniform bump heights. Thereby, a rework rate can be reduced, and the throughput and yield can both be improved. Further, silver is more cost-effective than gold. In addition, silver is able to effectively preclude the formation of the IMCs, such that the reliability of the stud bumps can be enhanced.

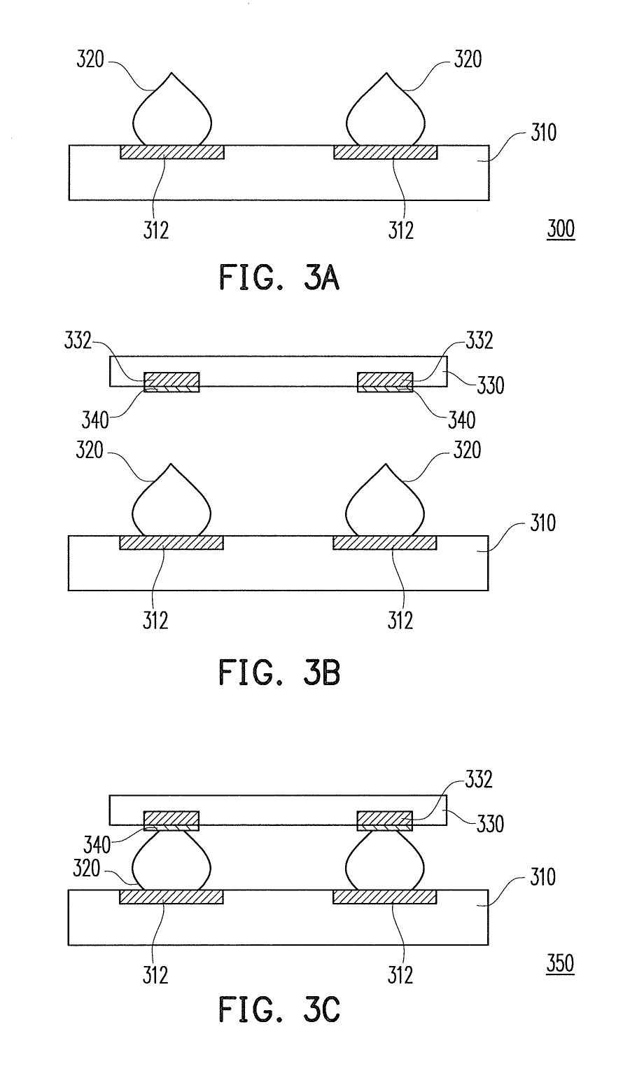

FIGS. 3A through 3C are schematic views of a chip package structure and a process of fabricating the same according to a second embodiment of the present invention. Referring to FIG. 3A, a chip package structure 300 includes a substrate 310 and a plurality of stud bumps 320. The substrate 310 is, for example, a printed circuit board, and the substrate 310 has a plurality of contact pads 312 made of copper, for example. The stud bumps 320 are bump-shaped gold balls formed by melting gold wires with use of a wire-bonding machine. After the gold balls are pressed onto the bonding pads 312, the gold wires are cut off. The formation of the stud bumps 320 on the substrate 310 can prevent the wire-bonding machine from exerting an excessive strength to the chip. As such, integrated circuits within the chip are not damaged. Additionally, it is more cost-effective to fabricate the stud bumps 320 on the substrate 310. Besides, the yield and the throughput can be improved while the rework rate can be reduced.

Next, a flip chip bonding process is carried out. As shown in FIG. 3B, the chip 330 is flipped around, and a sucking device (not shown) is employed for sucking a back surface of the chip 330. Thereby, the chip 330 is electrically connected to the substrate 310 through a solder layer 340, and then a chip package structure 350 indicated in FIG. 3C is formed. The solder layer 340 is formed on bonding pads 332 of the substrate 330 by printing, for example, and the solder layer 340 can be made of a solder paste, a lead-free solder, and so on. Here, the solder layer 340 is utilized for bonding the stud bumps 320 disposed on the substrate 310, such that the chip 330 can be fixed to the substrate 310. In the present embodiment, a method of fixing the chip 330 to the substrate 310 is, for example, a thermocompression method, such that the gold bumps and the solder layer 340 can result in the gold-tin eutectic alloy, and the bonding strength between the gold bumps and the solder layer 340 can be improved as well. In addition, referring to FIG. 5, the solder layer not only can be formed on the bonding pads 332 of the chip 330, but also can be formed on each of the stud bumps 320 according to another embodiment. For instance, a required solder layer 340a can be formed by adhering the solder to the stud bumps 320 without fabricating a stencil, thus reducing the manufacturing costs. On the other hand, the chip can also be fixed to the substrate by performing an ultrasonic vibration bonding process in no need of forming the solder layer 340 on the bonding pads 332 of the chip 330 or forming the solder layer 340a on the stud bumps 320. Thereby, the manufacturing process can be simplified.

It should be noted that the stud bumps 320 of the present invention are made of a gold-silver alloy containing 15% or less than 15% of silver by weight, and silver would be diffused to the solder layer 340, such that the solder layer 340 no longer contains tin only. An alloy containing 0.5%˜3.5% of silver by weight is then formed. During the soldering operation, the formation of the IMCs and the loss of gold can be prevented because the solder layer 340 is composed of a silver-diffusion constituent.

To sum up, according to the present invention, the stud bumps used in the chip structure, the substrate structure, the chip package structure, and the process of fabricating the chip package structure are made of the gold-silver alloy containing 15% or less than 15% of silver by weight, so as to prevent the gold of the stud bumps from diffusing to the solder layer or to resist the formation of the IMCs when the stud bumps are welded to the solder layer. In comparison with the conventional gold wires containing 99% of gold, the gold wires of the present invention are characterized by better wire bonding strength, greater bond-off performance, and uniform bump heights. Thereby, the rework rate can be reduced, and the throughput and yield can both be improved.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

What is claimed is:

1. A chip structure, comprising:
a chip, having an active surface where at least a bonding pad is disposed; and
at least a stud bump, disposed on the bonding pad of the chip, wherein the stud bump is made of a gold-silver alloy, and the percentage of silver is equal to or less than 15% by weight.

2. The chip structure as claimed in claim 1, further comprising a solder layer disposed on the stud bump.

3. A substrate structure, comprising:
a substrate, having at least a contact pad; and
at least a stud bump, disposed on the contact pad of the substrate, wherein the stud bump is made of a gold-silver alloy, and the percentage of silver is equal to or less than 15% by weight.

4. The substrate structure as claimed in claim 3, further comprising a solder layer disposed on the stud bump.

5. A chip package structure, comprising:
a substrate, having at least a contact pad;
a chip, having an active surface where at least a bonding pad is disposed; and
at least a stud bump, disposed on the contact pad of the substrate or on the bonding pad of the chip, wherein the stud bump is made of a gold-silver alloy, and the percentage of silver is equal to or less than 15% by weight.

6. The chip package structure as claimed in claim 5, wherein the stud bump is disposed on the contact pad of the substrate, and the chip package structure further comprises a solder layer interposed between the stud bump and the bonding pad of the chip.

7. The chip package structure as claimed in claim 5, wherein the stud bump is disposed on the bonding pad of the chip, and the chip package structure further comprises a solder layer interposed between the stud bump and the contact pad of the substrate.
